(19) United States
(12) Patent Application Publication
(10) Pub. No.: US 2026/0139742 A1
(43) Pub. Date: May 21, 2026

(54) NON-SEALED BUTTERFLY VALVE

(71) Applicant: CKD CORPORATION, Komaki-shi (JP)

(72) Inventors: Chiharu INOMATA, Komaki-shi (JP); Nobuhiro Fukukawa, Komaki-shi (JP); Yasunori Nishimura, Komaki-shi (JP)

(73) Assignee: CKD CORPORATION, Komaki-shi (JP)

(21) Appl. No.: 19/369,419

(22) Filed: Oct. 27, 2025

(30) Foreign Application Priority Data
Nov. 20, 2024 (JP) 2024-202704

(51) Int. Cl. F16K 1/22; F16K 1/50; F16K 51/02

(52) U.S. Cl. CPC F16K 1/222; F16K 1/50; F16K 51/02

(57) ABSTRACT

In a non-sealed butterfly valve, a butterfly valve element includes maximum outer diameter portions facing the inner peripheral surface of a flow passage when the butterfly valve element is in a valve-closed position and first chamfered portions reducing the diameter of the butterfly valve element from the maximum outer diameter portions in a direction opposite a rotation direction of the butterfly valve element rotating from the valve-closed position to a valve-open position. The maximum outer diameter portions are provided point-symmetrically about the axis of a rotary shaft, and the first chamfered portions are provided point-symmetrically about the axis of the rotary shaft.

### CROSS-REFERENCE TO RELATED APPLICATIONS

This application is based upon and claims the benefit of priority to Japanese Patent Application No. 2024-202704 filed on November 20, 2024, the entire contents of which are incorporated herein by reference.

### BACKGROUND

### Technical field

The disclosure relates to a non-sealed butterfly valve installed on a pipe connecting a vacuum vessel and a vacuum pump to control the pressure in the vacuum vessel and provided with a flow passage, a rotary shaft placed in a direction perpendicular to the flow passage, a disc-shaped butterfly valve element rotatable about the axis of the rotary shaft, between a closed position for minimizing the flow passage area of the flow passage and an open position for maximizing the flow passage area.

### Related Art

Conventional semiconductor manufacturing processes include a process of controlling the pressure in a vacuum vessel to create a vacuum, and then supplying gas to the vacuum vessel.

As a device for controlling the pressure in the vacuum vessel, a butterfly valve is used. The details are as follows. The butterfly valve is placed between the vacuum vessel and the vacuum pump. When the butterfly valve is opened, the internal pressure of the vacuum vessel is reduced by the vacuum pump. Once a specified amount of gas is introduced into the vacuum vessel and a required pressure state (i.e., a vacuum state) is reached, a valve element of the butterfly valve is maintained at that opening degree.

One example of the butterfly valve conventionally known is disclosed in Japanese unexamined patent application publication No. 2021-124133 (JP 2021-124133A). The butterfly valve disclosed in JP 2021-124133A is a non-sealed butterfly valve configured to make a gap between the inner peripheral surface of the flow passage and the outer peripheral surface of the butterfly valve element even when this valve element is closed, i.e., is located in a valve-closed state. General butterfly valve elements are each configured to perfectly close a flow passage in the valve-closed state using a seal member. However, the use of the seal member during pressure control may decrease the product life due to wear or abrasion. For this reason, non-sealed butterfly valves are preferred.

### SUMMARY

### Technical Problems

However, the above-described conventional art has the following problems. Since the butterfly valve disclosed in JP 2021-124133A is a non-sealed type, even when this valve is closed, gas is drawn in by the vacuum pump through the gap between the butterfly valve element and the flow passage. Thus, the internal pressure of the vacuum vessel supplied with gas may not be maintained at a required pressure level. In particular, in order to achieve a wider pressure control range, a non-sealed butterfly valve is demanded to achieve smaller conductance, i.e., to suppress the gas from passing through the gap between the butterfly valve element and the flow passage while the valve is in the valve-closed state or at a small or slight opening degree (e.g., an opening degree of 10° or less).

In the butterfly valve disclosed in JP 2021-124133A, if the butterfly valve element is designed with an increased thickness, it is possible to reduce the conductance in the valve-closed state or at a slight opening degree. However, as the thickness of the butterfly valve element increases, the flow passage area of the flow passage when the valve is in a valve-open state decreases, resulting in a decrease in conductance. This conductance decrease in the valve-open state is undesirable because it leads to a decrease in efficiency of pressure control. It is therefore desired to reduce the conductance in the valve-closed state or at the slight opening degree while avoiding a conductance decrease in the valve-open state.

The disclosure has been made to address the above problems and has a purpose to provide a non-sealed butterfly valve capable of achieving a wider pressure control range by reducing conductance in a valve-closed state or at a slight opening degree while avoiding a decrease in conductance in a valve-open state.

### Means of Solving the Problems

To achieve the above-mentioned purpose, one aspect of the disclosure provides a non-sealed butterfly valve configured as below.

(1) A non-sealed butterfly valve to control pressure in a vacuum vessel according to the disclosure is configured to includes: a flow passage; a rotary shaft placed extending in a direction perpendicular to the flow passage; and a butterfly valve element having a circular disk shape, coupled to the rod and configured to rotate about an axis of the rotary shaft, between a valve-closed position for minimizing a flow passage area of the flow passage and a valve-open position for maximizing the flow passage area, wherein the butterfly valve element includes: maximum outer diameter portions facing an inner peripheral surface of the flow passage when the butterfly valve element is in the valve-closed position and being provided point-symmetrically about the axis of the rotary shaft when viewed in an axial direction of the rotary shaft; and chamfered portions reducing a diameter of the butterfly valve element from the maximum outer diameter portions in a direction opposite a rotation direction of the butterfly valve element that rotates from the valve-closed position to the valve-open position and being provided point-symmetrically about the axis of the rotary shaft when viewed in an axial direction of the rotary shaft.

(2) In the non-sealed butterfly valve described in (1), a dimension of each of the maximum outer diameter portions in a thickness direction of the butterfly valve element may be greater than 0.5% and equal to or less than 10% of the flow passage.

(3) In the non-sealed butterfly valve described in (1) or (2), an angle of each of the chamfered portions relative to a thickness direction of the butterfly valve element may be equal to or less than 30°.

(4) In the non-sealed butterfly valve described in any one of (1) to (3), the butterfly valve element may include second chamfered portions reducing the diameter of the butterfly valve element from the maximum outer diameter portions in the rotation direction, the second chamfered portions being provided symmetrically about the axis of the rotary shaft when viewed in the axial direction of the rotary shaft.

(5) In the non-sealed butterfly valve described in any one of (1) to (4), the chamfered portions may have an angle with respect to an axis of the maximum outer diameter portions.

(6) The non-sealed butterfly valve described in any one of (1) to (5) may be configured to further include a rotation restricting part for restricting the butterfly valve element from rotating in the direction opposite the rotation direction.

(7) The non-sealed butterfly valve described in (1) or (2) may be configured to further include further comprising a rotation restricting part for restricting the butterfly valve element from further rotating from the valve-open position in the rotation direction.

The non-sealed butterfly valve of the disclosure configured as above can reduce the conductance in the valve-closed state or at the slight opening degree while avoiding a decrease in conductance in the valve-open state.

### BRIEF DESCRIPTION OF THE DRAWINGS

FIG. 1 is a schematic diagram of a vacuum pressure control system using a non-sealed butterfly valve in an embodiment;

FIG. 2 is a cross-sectional view of the non-sealed butterfly valve taken in a direction parallel to the axis of a rotary shaft and parallel to a flow passage in the embodiment;

FIG. 3 is a cross-sectional view of the non-sealed butterfly valve taken in a direction parallel to the axis of the rotary shaft and perpendicular to the flow passage in the embodiment;

FIG. 4 is a cross-sectional view of the non-sealed butterfly valve taken in a direction perpendicular to the axis of the rotary shaft and parallel to the flow passage in the embodiment, showing a state of the butterfly valve element located in a closed position;

FIG. 5 is a partial enlarged view of a section A in FIG. 4;

FIG. 6 is a diagram showing the positional relationship between a rotation restricting part and a butterfly valve element;

FIG. 7 is a diagram showing the positional relationship between the rotation restricting part and the butterfly valve element;

FIG. 8 is a cross-sectional view, similar to FIG. 4, showing the non-sealed butterfly valve using a butterfly valve element in a modified example;

FIG. 9 is a perspective view of the butterfly valve element in the modified example;

FIG. 10 is a graph showing the relationship between rotation angle of the butterfly valve element and pressure in a vacuum vessel; and

FIG. 11 is a cross-sectional view, similar to FIG. 4, showing the non-sealed butterfly valve using the butterfly valve element in another modified example.

### DETAILED DESCRIPTION OF THE EXEMPLARY EMBODIMENTS

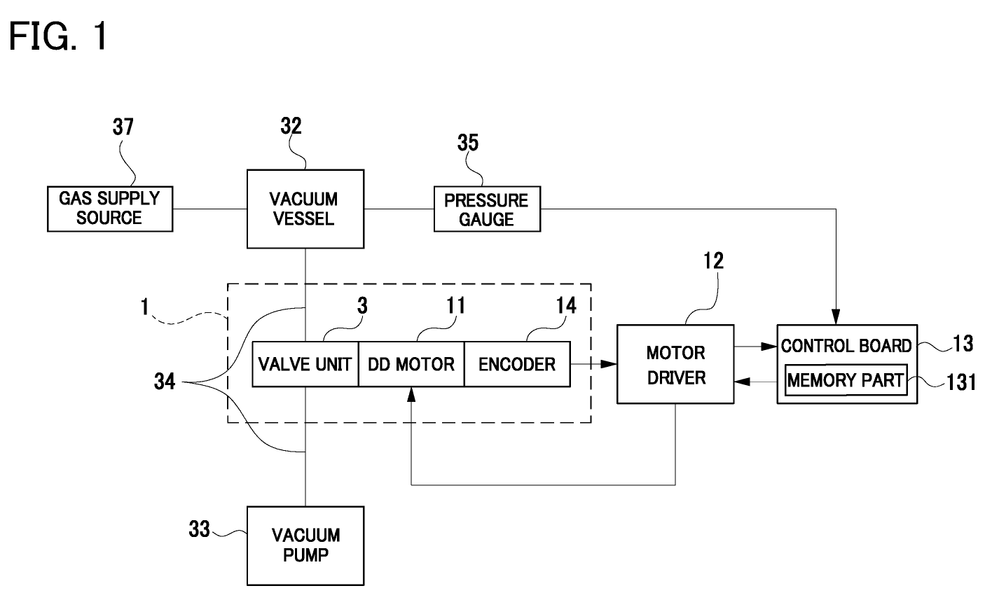

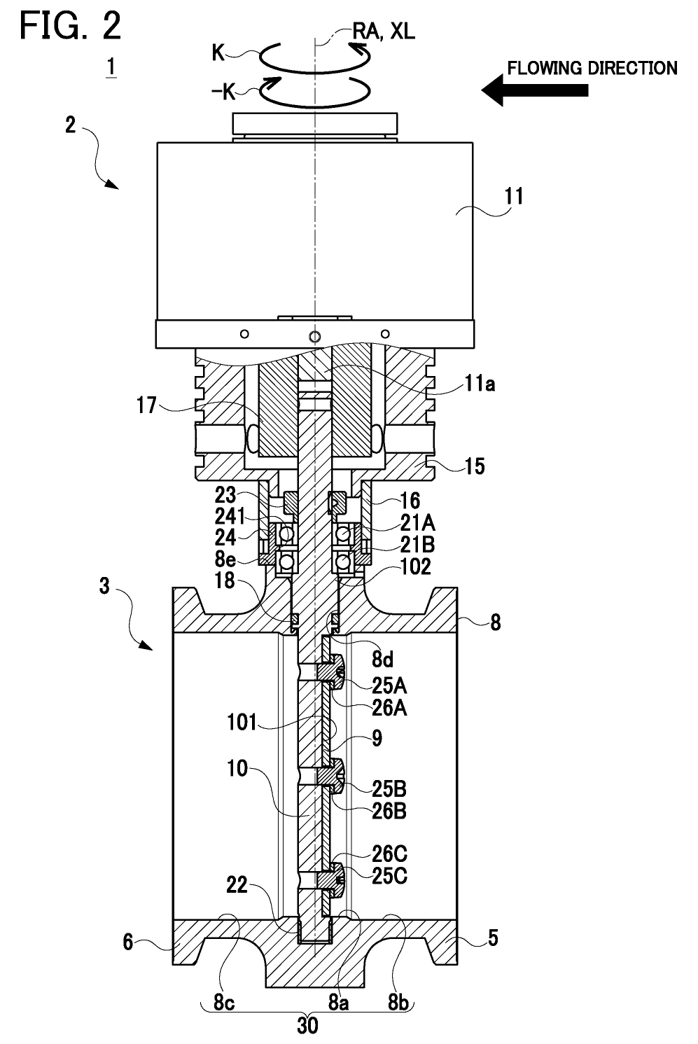

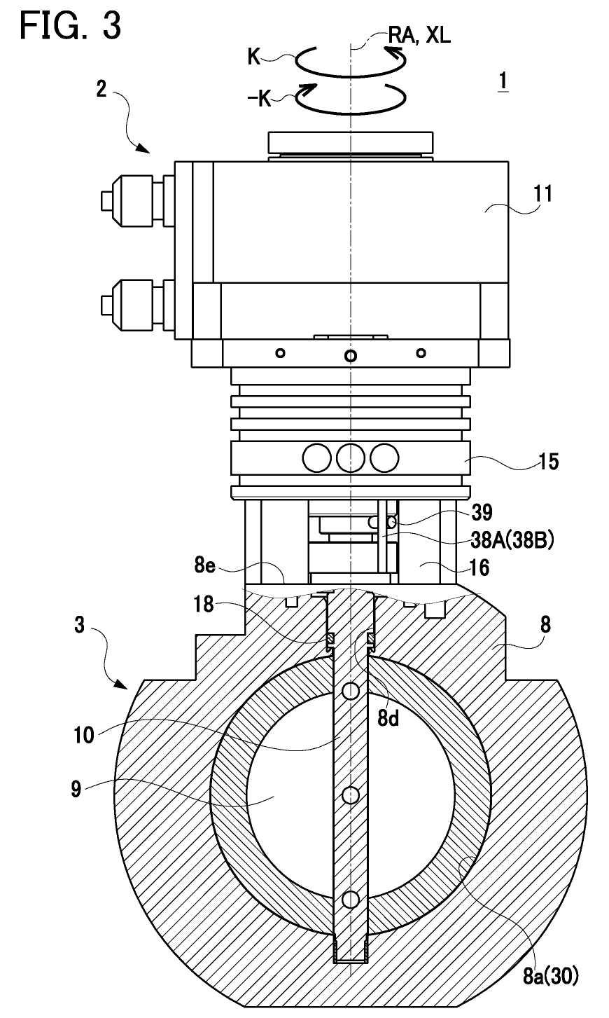

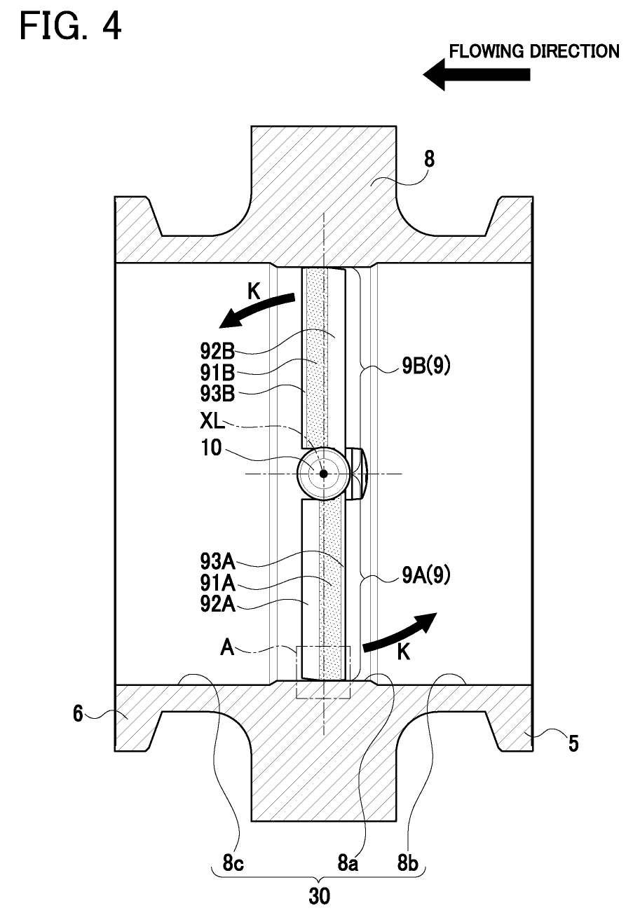

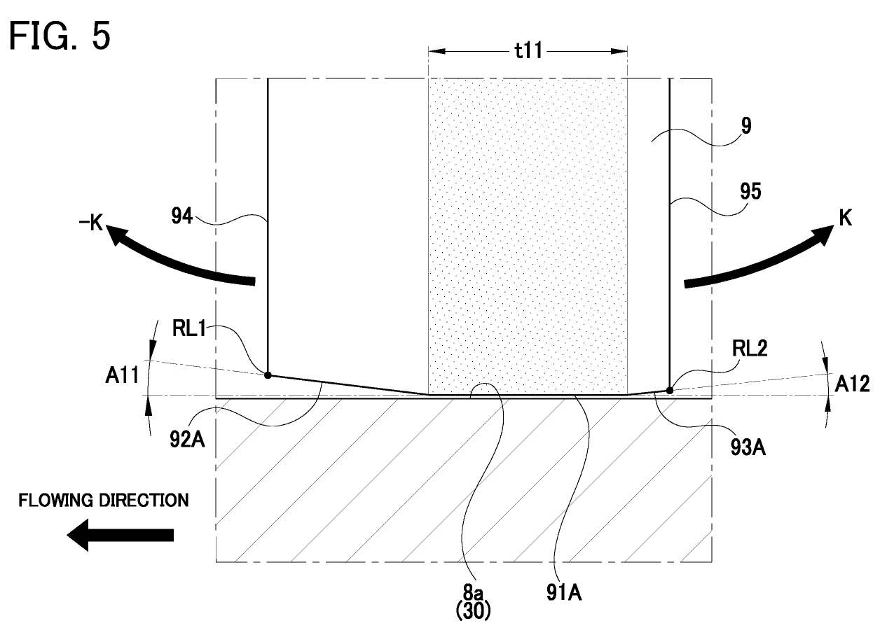

A detailed description of an embodiment of a non-sealed butterfly valve of the disclosure will now be given referring to the accompanying drawings. FIG. 1 is a schematic diagram of a vacuum pressure control system using a non-sealed butterfly valve 1 in the embodiment. FIG. 2 is a cross-sectional view of the non-sealed butterfly valve 1 taken in a direction parallel to the axis XL of a rod 10 (one example of a rotary shaft of the disclosure) and parallel to a flow passage 30 in the embodiment. FIG. 3 is a cross-sectional view of the non-sealed butterfly valve 1 taken in a direction parallel to the axis XL of a rod 10 and perpendicular to the flow passage 30 in the embodiment. FIG. 2 and FIG. 3 both show a valve-closed state. FIG. 4 is a cross-sectional view of the non-sealed butterfly valve 1 taken in a direction perpendicular to the axis XL of the rod 10 and parallel to the flow passage 30 in the embodiment, showing a state of a butterfly valve element 9 located in the valve-closed position. In FIG. 4, the butterfly valve element 9 is illustrated showing its outer peripheral edge, not a cross-section. FIG. 5 is a partial enlarged view of a section A in FIG. 4. A fluid flowing through the flow passage 30 flows from right to left in FIGS. 2, 4, and 5. That is, in FIGS. 2, 4, and 5, the right side is an upstream side and the left side is a downstream side. In FIG. 3, the far side is the upstream side and the near side is the downstream side. In FIGS. 4 and 5, dots on the butterfly valve element 9 are applied for easy viewing of the shape of the outer peripheral edge of the butterfly valve element 9, and do not represent the surface shape, the surface state or condition, and others.

The non-sealed butterfly valve 1 in the embodiment, which will be simply referred to as a butterfly valve 1, is used as, for example, a vacuum pressure control device for controlling the internal pressure of a vacuum vessel 32 in a semiconductor manufacturing process. The butterfly valve 1 is placed on a pipe 34 connecting the vacuum vessel 32 and a vacuum pump 33 as shown in FIG. 1. The vacuum vessel 32 can be supplied with gas from a gas supply source 37. The vacuum pump 33 is used to exhaust gas from the vacuum vessel 32 via the pipe 34. The butterfly valve 1 is operated to adjust the opening degree of the butterfly valve element 9, thereby regulating the amount of gas to be exhausted using the vacuum pump 33 to control the pressure in the vacuum vessel 32.

### Configuration of Butterfly Valve

The butterfly valve 1 includes a drive unit 2 and a valve unit 3 as shown in FIG. 2 and 3. The drive unit 2 includes a direct-drive motor (hereinafter, a DD motor) 11. This DD motor 11 is connected to a motor driver 12 and an encoder 14 as shown in FIG. 1. The motor driver 12 is connected to a control board 13. The DD motor 11 does not need any intermediate mechanism such as a reduction gear or the like. This configuration can make the drive unit 2 compact, reduce noise, and further improve response performance, speed stability, and positioning accuracy. Thus, the butterfly valve 1 can achieve the vacuum pressure control with high accuracy. The DD motor 11 has an output shaft 11a as shown in FIG. 2. This output shaft 11a rotates about the axis RA.

The control board 13 is connected to the motor driver 12 and a pressure gauge 35 for detecting the internal pressure of the vacuum vessel 32 as shown in FIG. 1. The control board 13 includes a memory part 131 that stores, for example, a valve-closed position and a valve-open position of the butterfly valve element 9, and a rotation angle of the output shaft 11a (i.e., a rotation angle of the butterfly valve element 9 which will be described later) corresponding to an arbitrary target pressure of the vacuum chamber 32, and others. Based on the rotation angle read out from the memory part 131, the motor driver 12 controls the rotation of the DD motor 11 (the output shaft 11a).

The output shaft 11a is connected to one end (an upper end in FIG. 2) of the rod 10 inserted in the valve unit 3, via a metal plate spring coupling 17, as shown in FIG. 2. The rod 10 is positioned with its axis XL (see FIG. 4) coaxial with the axis RA of the output shaft 11a. Accordingly, the rod 10 rotates about the axis XL as the output shaft 11a rotates. The output shaft 11a and the rod 10 are connected to each other via the coupling 17. In addition, the drive unit 2 is connected to the valve unit 3 via a motor base 15 and a shaft block 16.

The valve unit 3 connected to the drive unit 2 includes a valve body 8 and a butterfly valve element 9. The valve body 8 is made of stainless steel that is resistant to corrosion.

The valve body 8 includes a joint 5 at an upstream end (a right end in FIG. 2 and FIG. 4) and a joint 6 at a downstream end (a left end in FIG. 2 and FIG. 4). The inner peripheral surface of the joint 5 defines an inlet passage 8b and the inner peripheral surface of the joint 6 defines an outlet passage 8c. A valve hole 8a, defined by an inner peripheral surface having a circular-arc cross-section in FIG. 3, is formed between the inlet passage 8b and the outlet passage 8c. As shown in FIG. 2, the inlet passage 8b, the valve hole 8a, and the outlet passage 8c are located coaxially and communicated with each other, constituting the flow passage 30 in a continuous form. In the semiconductor manufacturing process, as shown in FIG. 1, the joint 5 is connected to the vacuum vessel 32 via the pipe 34 and the joint 6 is connected to the vacuum pump 33 via the pipe 34. The thus configured butterfly valve 1 operates to exhaust gas from the vacuum vessel 32 through the flow passage 30.

Furthermore, the valve body 8 includes an insertion hole 8d, one end of which opens on the end face (the upper end face) 8e connected to the drive unit 2, while the other end communicates with the valve hole 8a, as shown in FIG. 2 and FIG. 3. In this insertion hole 8d, the rod 10 is inserted. The rod 10 inserted in the insertion hole 8d extends across the valve hole 8a in a direction perpendicular to the flow passage 30.

The rod 10 is made of corrosion-resistant stainless steel machined into a columnar shape. A part of the rod 10, inserted in the flow passage 30, is provided with a valve-element mounting part 101 having a nearly D-shaped cross-section in a direction perpendicular to the axis RA.

An O-ring 18 is placed between the rod 10 and the inner peripheral surface of the insertion hole 8d to seal therebetween. The O-ring 18 is compressed by the outer peripheral surface of the rod 10 and the inner peripheral surface of the insertion hole 8d, thus preventing a fluid flowing through the flow passage 30 from leaking toward the drive unit 2 via the insertion hole 8d.

One end of the rod 10 on the side inserted in the flow passage 30 (i.e., the lower end in FIG. 2 and FIG. 3) is rotatably supported by a bush 22. The bush 22 is made of resin with high corrosion resistance and good sliding properties. Furthermore, a part of the rod 10, located between the upper end face 8e of the valve body 8 and the motor base 15, is rotatably supported by two ball bearings 21A and 21B adjacently arranged in the axial direction of the rod 10. Since both ends of the rod 10 are double-supported by the ball bearings 21A, 21B and the bush 22, the rod 10 can be supported in such a state where its rotation axis, i.e., axis XL, is stable and less likely to deflect or wobble.

Each of the ball bearings 21A and 21B is pressurized from above and below by a collar 23, a protrusion 241 of a bearing retainer 24, and a flange part 102 of the rod 10. Thus, each of the ball bearings 21A and 21B is less likely to generate internal gaps. The ball bearings 21A and 21B pressurized as above can enhance their rigidity, thereby suppressing vibrations of the rod 10 during rotation and prevent deflecting or wobbling of the rotational center axis (the axis XL) of the rod 10.

The butterfly valve element 9 is coupled to the rod 10 with screws 25A, 25B, and 25C and washers 26A, 26B, and 26C as shown in FIG. 2. Those three screws 25A to 25C are all the same kind of screws, and those three washers 26A to 26C are all the same kind of washers.

Since the butterfly valve element 9 is connected to the rod 10, when the output shaft 11a of the DD motor 11 rotates about the axis RA in a direction K or in an opposite direction -K, the rod 10 connected to the output shaft 11a via the coupling 17 is rotated about the axis XL (see FIG. 4) in the same direction as the output shaft 11a, causing the butterfly valve element 9 to rotate in the same direction.

More specifically, as the output shaft 11a rotates about the axis RA in the direction K from a state where the butterfly valve element 9 is in the valve-closed position, the butterfly valve element 9 is rotated in the same direction. The position at which the rotation angle of the butterfly valve element 9 is 90° (i.e., the position to which the butterfly valve element 9 rotates 90° in the direction K from the position shown in FIG. 4) corresponds to the valve-open position at which the flow passage area of the flow passage 30 (the valve hole 8a) is maximum. This enables exhaust of a large amount of gas from the vacuum vessel 32.

In contrast, when the output shaft 11a of the DD motor 11 rotates 90° about the axis RA in the direction -K from the state where the butterfly valve element 9 is in the valve-open position, the rod 10 rotates in the direction -K, coming into the valve-closed position at which the butterfly valve element 9 closes the valve hole 8a as shown in FIG. 4. However, a gap is provided between the butterfly valve element 9 and the flow passage 30 (the valve hole 8a), the detail of which will be described later. Therefore, the valve-closed position indicates a state where the butterfly valve element 9 does not perfectly close the valve hole 8a, thereby minimizing the flow passage cross-sectional area of the flow passage 30 (the valve hole 8a).

The butterfly valve 1 includes a rotation restricting part in order to restrict the butterfly valve element 9 from rotating from the valve-closed position in the direction -K or further rotating from the valve-open position in the direction K. In the present embodiment, the rotation restricting part is mainly constituted of a pin 39 and stoppers 38A and 38B, which are placed between the valve body 8 and the motor base 15, as shown in FIG. 3.

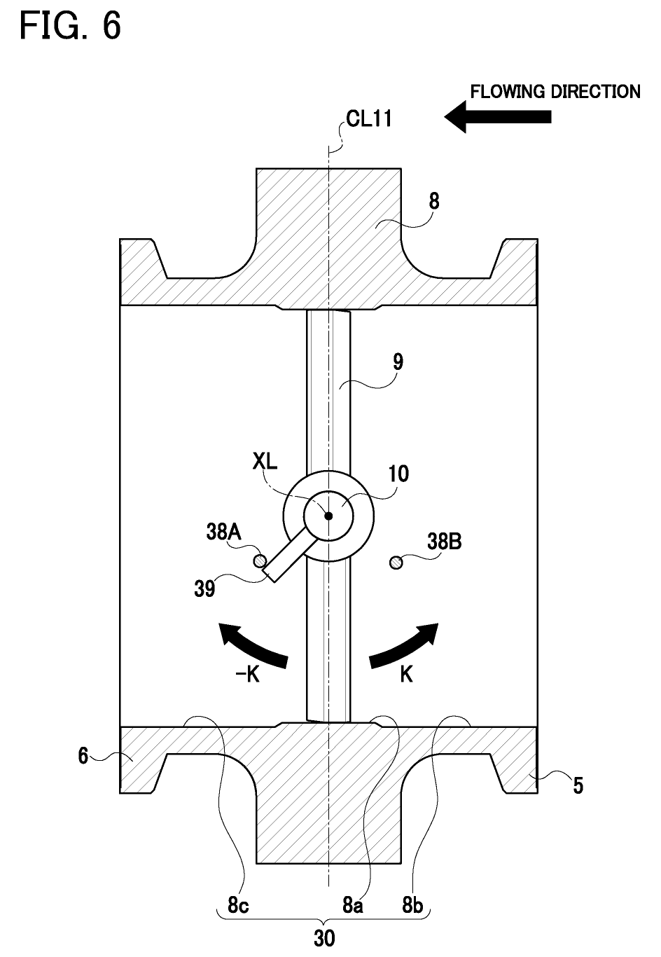

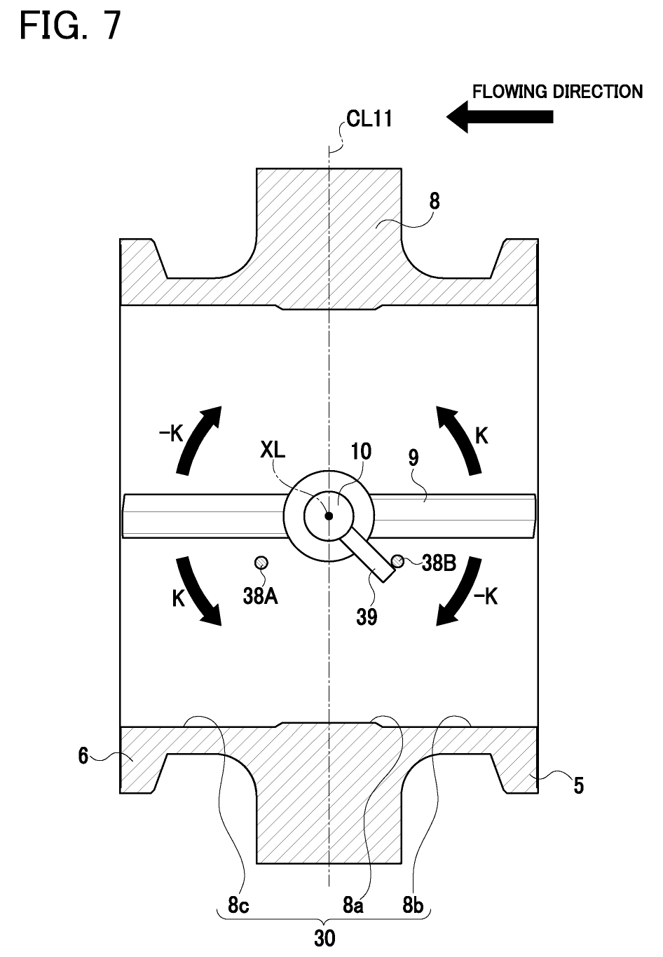

The pin 39 is fixed to the rod 10 and extends outward in the radial direction of the rod 10 as shown in FIG. 6 and FIG. 7. Accordingly, the pin 39 rotates about the axis XL in association with the rotation of the rod 10 in the direction K or -K. The stoppers 38A and 38B are pin-shaped members extending in parallel to the rod 10, i.e., in a vertical direction in FIG. 3. The stoppers 38A and 38B are arranged line-symmetrically about the central axis CL11 intersecting with the axis XL, as shown in FIG. 6 and FIG. 7. In FIG. 3, accordingly, only the stopper 38A is visible and the stopper 38B located on the far side is hidden behind the stopper 38A.

Here, the positional relationship between the pin 39 and the stoppers 38A, 38B will be described referring to FIG. 6 and FIG. 7. FIG. 6 and FIG. 7 are diagrams showing the positional relationship between the rotation restricting part (i.e., in the present embodiment, the pin 39 and the stoppers 38A, 38B) and the butterfly valve element 9.

When the butterfly valve element 9 is at the valve-closed position, as shown in FIG. 6, the pin 39 is located near the downstream-side stopper 38A. At that time, a slight gap exists between the pin 39 and the stopper 38A, so that the pin 39 and the stopper 38A do not contact each other. However, if the butterfly valve element 9 is caused to further rotate from the valve-closed position in the direction -K due to a malfunction or other failure of the DD motor 11, the pin 39 comes into contact with the stopper 38A, restricting, or stopping, further rotation of the butterfly valve element 9. The reason why the slight gap is provided between the pin 39 and the stopper 38A while the butterfly valve element 9 is in the valve-closed position is to prevent the pin 39 from coming into contact with the stopper 38A due to manufacturing tolerances before the butterfly valve element 9 reaches the valve-closed position.

In contrast, when the butterfly valve element 9 is at the valve-open position, as shown in FIG. 7, the pin 39 is located near the upstream-side stopper 38B. At that time, a slight gap exists between the pin 39 and the stopper 38B, so that the pin 39 and the stopper 38B do not contact each other. However, if the butterfly valve element 9 is caused to further rotate from the valve-open position in the direction K due to a malfunction or other failure of the DD motor 11, the pin 39 comes into contact with the stopper 38B, restricting, or stopping, further rotation of the butterfly valve element 9. The reason why the slight gap is provided between the pin 39 and the stopper 38B while the butterfly valve element 9 is in the valve-open position is to prevent the pin 39 from coming into contact with the stopper 38B due to manufacturing tolerances before the butterfly valve element 9 reaches the valve-open position.

The butterfly valve element 9 is made of stainless steel which is corrosion-resistant and formed in a circular disc shape by machining. The butterfly valve element 9 has an outer peripheral edge shaped that a left half in the flowing direction, i.e., a lower-half section 9A in FIG. 4, at the valve-closed position and a right half in the flowing direction, i.e., an upper-half section 9B in FIG. 4, at the valve-closed position are point-symmetrical about the axis XL of the rod 10 when viewed in the axial direction of the rod 10. The details thereof will be described below.

The outer peripheral edge of the section 9A of the butterfly valve element 9 is formed with a maximum outer diameter portion 91A, a first chamfered portion 92A, and a second chamfered portion 93A as shown in FIG. 4.

In the outer peripheral edge, the maximum outer diameter portion 91A has the maximum diameter. However, the diameter of the maximum outer diameter portion 91A is set smaller than the diameter of the flow passage 30 (i.e., the valve hole 8a). Thus, while the butterfly valve element 9 is in the valve-closed position, the maximum outer diameter portion 91A faces the inner peripheral surface of the flow passage 30 (i.e., the valve hole 8a) in parallel, making a gap of several tens to several hundreds of micrometer (μm) between the flow passage 30 (i.e., the valve hole 8a) and the maximum outer diameter portion 91A. In other words, the flow passage 30 (i.e., the valve hole 8a) is not perfectly sealed even when the butterfly valve element 9 is in the valve-closed position. Therefore, gas is allowed to be exhausted from the vacuum vessel 32 by the suction power of the vacuum pump 33 without stopping exhaust of gas.

A dimension t11 (see FIG. 5) of the maximum outer diameter portion 91A in the thickness direction of the butterfly valve element 9 is preferably more than 0.5% but 10% or less of the inner diameter of the flow passage 30 (the valve hole 8a). In the present embodiment, for 100 mm of the inner diameter of the flow passage 30 (the valve hole 8a), the dimension t11 is set to greater than about 0.5 mm but 10 mm or less.

The first chamfered portion 92A is sloped so that the diameter of the butterfly valve element 9 decreases from the maximum outer diameter portion 91A in a direction opposite the direction K (i.e., in a downstream direction). The angle A11 of the first chamfered portion 92A is set to, for example, 30° or less relative to the thickness direction of the butterfly valve element 9. However, this taper angle has to be set so that, when the butterfly valve element 9 rotates in the direction K, the ridge line RL1 at which the first chamfered portion 92A and the downstream-side end face 94 of the butterfly valve element 9 intersect each other does not interfere with the inner peripheral surface of the flow passage 30 (i.e., the valve hole 8a).

The second chamfered portion 93A is sloped so that the diameter of the butterfly valve element 9 decreases from the maximum outer diameter portion 91A in the direction K (i.e., in an upstream direction). The angle A12 of the second chamfered portion 93A is preferably set as small as possible relative to the thickness direction of the butterfly valve element 9. However, this taper angle has to be set so that, when the butterfly valve element 9 rotates from the valve-closed position in the direction -K and the pin 39 comes into contact with the stopper 38A, the ridge line RL2 at which the second chamfered portion 93A and the upstream-side end face 95 of the butterfly valve element 9 intersect each other does not interfere with the inner peripheral surface of the flow passage 30 (i.e., the valve hole 8a).

The outer peripheral edge of the section 9B of the butterfly valve element 9 is formed with a maximum outer diameter portion 91B, a first chamfered portion 92B, and a second chamfered portion 93B as shown in FIG. 4. These maximum outer diameter portion 91B, first chamfered portion 92B, and second chamfered portion 93B are formed in point-symmetrical shape, about the axis XL, with respect to the maximum outer diameter portion 91A, first chamfered portion 92A, and second chamfered portion 93A formed in the outer peripheral edge of the section 9A, respectively.

Consequently, in contrast to the first chamfered portion 92A of the section 9A, the first chamfered portion 92B is sloped so that the diameter of the butterfly valve element 9 decreases from the maximum outer diameter portion 91B in the upstream direction. However, similar to the first chamfered portion 92A, the first chamfered portion 92B reduces the diameter of the butterfly valve element 9 in the direction opposite the direction K. Further, the taper angle of the first chamfered portion 92B relative to the thickness direction of the butterfly valve element 9 is also set as with the angle A11 described above.

In contrast to the second chamfered portion 93A of the section 9A, the second chamfered portion 93B is sloped so that the diameter of the butterfly valve element 9 decreases from the maximum outer diameter portion 91B in the downstream direction. However, similar to the second chamfered portion 93A, the second chamfered portion 93B reduces the diameter of the butterfly valve element 9 in the direction K. Further, the taper angle of the second chamfered portion 93B relative to the thickness direction of the butterfly valve element 9 is also set as with the angle A12 described above.

### Operations and Effects of Butterfly Valve

The butterfly valve 1 configured as above operates as below.

The butterfly valve element 9 makes a gap of several tens to several hundreds of micrometer (μm) with respect to the inner peripheral surface of the flow passage 30 (the valve hole 8a) even when the butterfly valve element 9 is in the valve-closed position shown in FIG. 4. Thus, the non-sealed butterfly valve 1 continuously evacuates the vacuum vessel 32. FIG. 4 shows the butterfly valve element 9 in the valve-closed position. The butterfly valve element 9 rotates at any rotation angle between the valve-closed position (a rotation angle of 0°) and the valve-open position (a rotation angle of 90°) to adjust the flow passage area of the flow passage 30 (the valve hole 8a) so that the internal pressure of the vacuum vessel 32 reaches a target pressure.

To achieve a wider pressure control range, it is necessary to further reduce the conductance in the valve-closed state or at a slight opening degree (e.g., an opening degree of 10° or less). In other words, it is necessary to suppress the amount of gas allowed to pass through the gap between the butterfly valve element 9 and the flow passage 30 (the valve hole 8a).

The butterfly valve element 9 of the butterfly valve 1 in the present embodiment includes the maximum outer diameter portions 91A and 91B, which face the inner peripheral surface of the flow passage 30 (the valve hole 8a) when the butterfly valve element 9 is in the valve-closed position. The maximum outer diameter portions 91A and 91B are arranged point-symmetrically about the axis XL when viewed in the axial direction of the rod 10. The butterfly valve element 9 also includes the chamfered portions (the first chamfered portions 92A and 92B) reducing the diameter of the butterfly valve element 9 from the maximum outer diameter portion 91A in the direction opposite the rotation direction (i.e., the direction K) of the butterfly valve element 9 rotating from the valve-closed position to the valve-open position. Therefore, while maintaining the thickness of the butterfly valve element 9 equivalent to the conventional one, the maximum outer diameter portion 91A, 91B in the thickness direction of the butterfly valve element 9 can be designed with a large size (i.e., the dimension t11). This configuration can reduce the conductance in the valve-closed state or at the slight opening degree (e.g., an opening degree of 10° or less) while avoiding a decrease in conductance in the valve-open state.

Furthermore, the size (the dimension t11) of each maximum outer diameter portion 91A, 91B in the thickness direction of the butterfly valve element 9 preferably exceeds 0.5% but is 10% or less of the inner diameter of the flow passage 30 (the valve hole 8a). If the dimension t11 is set to 0.5% or less of the inner diameter of the flow passage 30 (the valve hole 8a), the aforementioned effect of reducing the conductance is not sufficiently achieved. If the dimension t11 exceeds 10% of the inner diameter of the flow passage 30 (the valve hole 8a), the flow passage area of the flow passage 30 is small when the butterfly valve element 9 is placed in the valve-open state, causing a conductance decrease and leading to lowered efficiency of pressure control. In addition, the large first chamfered portions 92A and 92B cannot be designed large enough, which may cause the butterfly valve element 9 (the ridge line RL1) to interfere with the flow passage 30 (the valve hole 8a) during rotation in the direction K.

The butterfly valve 1 in the present embodiment is configured such that the angle A11 of the chamfered portion (the first chamfered portion 92A, 92B) relative to the thickness direction of the butterfly valve element 9 may be 30° or less. This can minimize the conductance in the valve-closed state or at the slight opening degree (e.g., an opening degree of 10° or less).

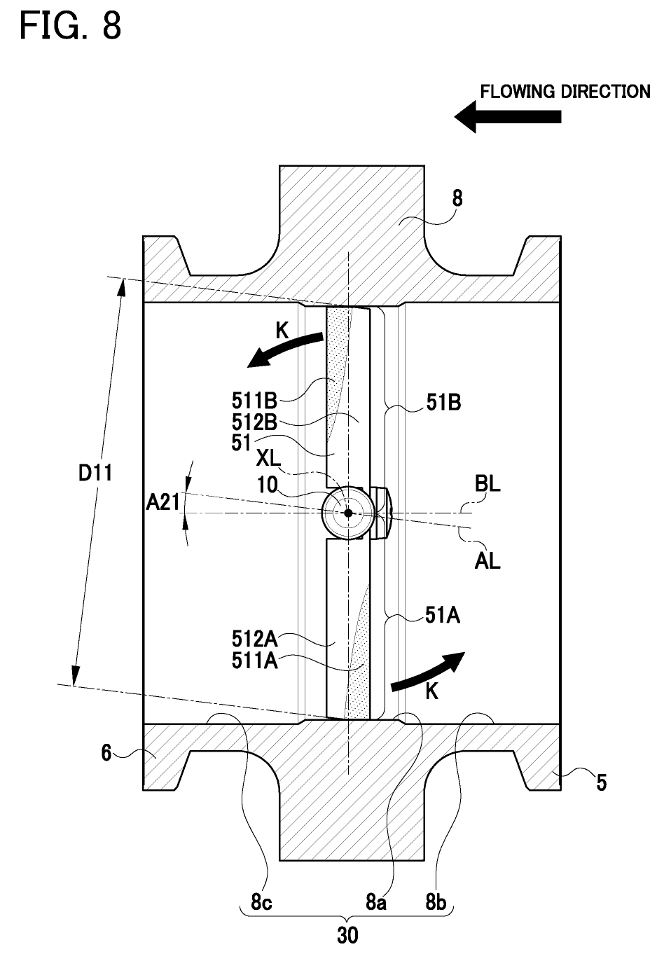

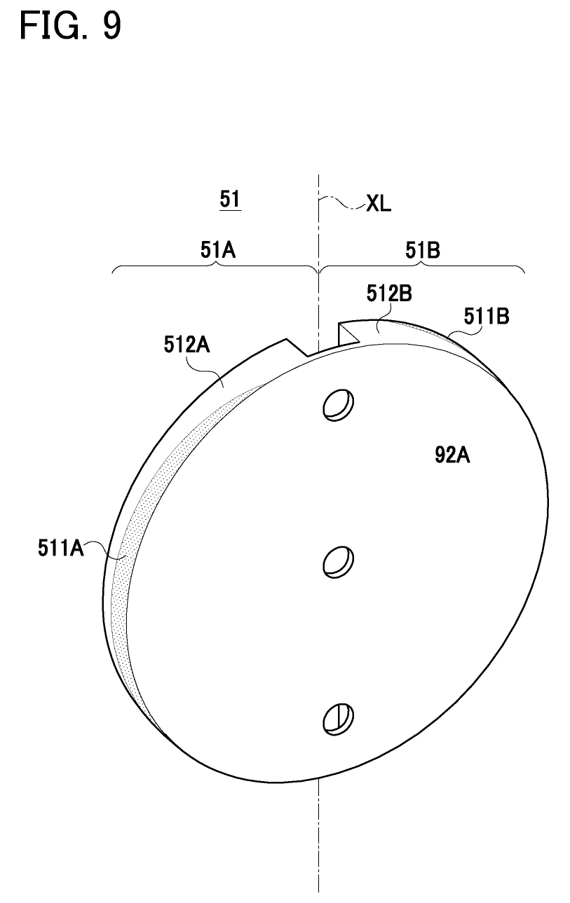

The shape of the butterfly valve element 9 described above is one example and may be configured as a butterfly valve element 51 shown in FIG. 8 and FIG. 9. FIG. 8 is a cross-sectional view, similar to FIG. 4, showing the non-sealed butterfly valve using the butterfly valve element 51 in a modified example. FIG. 9 is a perspective view of the butterfly valve element 51 in the modified example.

The axis of each of the first chamfered portions 92A and 92B of the butterfly valve element 9 is coaxial with the axis of the butterfly valve element 9. In contrast, as in the butterfly valve element 51 shown in FIG. 8 and FIG. 9, the axis AL of each of first chamfered portions 512A and 512B may be positioned at an angle A21 relative to the axis BL of the butterfly valve element 51. The axis BL of the butterfly valve element 51 is the axis of maximum outer diameter portions 511A and 511B and located coaxial with the flow passage 30. The axis AL of the first chamfered portions 512A, 512B is the axis when viewing the first chamfered portions 512A, 512B as a single column having the diameter D11.

In producing the butterfly valve element 9, the first chamfered portion 92A of the section 9A and the first chamfered portion 92B of the section 9B are formed in separate machining processes. As an alternative, when the axis AL of the first chamfered portion 512A, 512B is set at an angle relative to the axis BL of the butterfly valve element 51 as in the butterfly valve element 51, it is unnecessary to separate the machining processes for forming the first chamfered portion 512A in the section 51A and the first chamfered portion 512B in the section 51B.

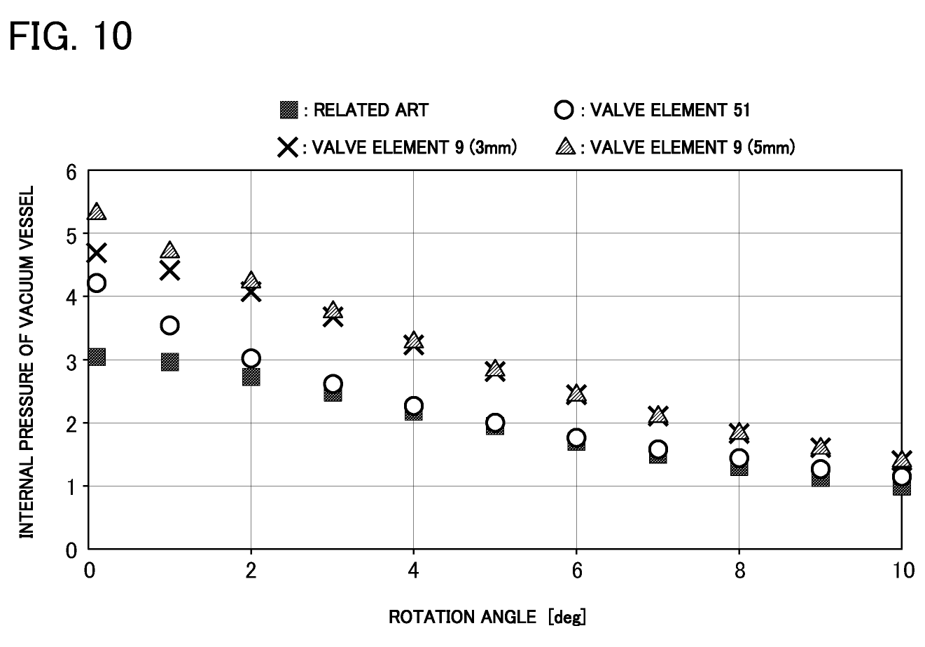

Next, the effect of reducing the conductance achieved by the butterfly valve elements 9 and 51 will be described below referring to FIG. 10. FIG. 10 is a graph showing the relationship between rotation angle of the butterfly valve element and internal pressure of the vacuum vessel.

The label on the horizontal axis of the graph, “ROTATION ANGLE”, represents the rotation angle of each butterfly valve element 9, 51. For example, “10 deg” indicates that the butterfly valve element has rotated 10° from the valve-closed position in the direction K. Further, the label on the vertical axis of the graph, “INTERNAL PRESSURE OF VACUUM VESSEL”, represents the pressure in the vacuum vessel 32 when gas is supplied from the gas supply source 37 to the vacuum vessel 32. It is to be noted that the values on the vertical axis do not represent specific pressure values and, instead, assuming that the internal pressure of the vacuum vessel 32 for the rotation angle of 10° in the conventional art is a reference value “1”, “2” on the vertical axis represents the internal pressure twice the reference value, “3” on the vertical axis represents the internal pressure three times the reference value, “4” on the vertical axis represents the internal pressure four times the reference value, “5” on the vertical axis represents the internal pressure five times the reference value, and “6” on the vertical axis represents the internal pressure six times the reference value. The higher the value on the vertical axis, the higher the internal pressure of the vacuum vessel is maintained, indicating that the conductance of the butterfly valve is smaller.

In the graph, the legend “related art” indicates that square marks represent the data obtained when using the butterfly valve element disclosed in JP 2021-124133A, the legend “valve element 51” indicates that circular marks represent the data obtained when using the butterfly valve element 51, the legend “valve element 9 (3 mm)” indicates that x marks represent the data obtained when using the butterfly valve element 9 having a dimension t11 of 3 mm, and the legend “valve element 9 (5 mm)” indicates that triangular marks represent the data obtained when using the butterfly valve element 9 having a dimension t11 of 5 mm.

As is understood from FIG. 10, for all the data indicated by legends “related art”, “valve element 51”, “valve element 9 (3 mm)”, and “valve element 9 (5 mm)”, the internal pressure of the vacuum vessel rises as the rotation angle becomes smaller. This is because the smaller the rotation angle, the more the flow passage area of the flow passage 30 (the valve hole 8a) is restricted, reducing the conductance.

The data indicated by “valve element 51” show that the internal pressure of the vacuum vessel 32 is generally maintained at a higher level, i.e., the conductance is reduced, than the data indicated by “related art” at a rotation angle of 0 to 10 deg. In particular, the internal pressure of the vacuum vessel 32 at a rotation angle of 2 deg, indicated by “valve element 51”, rises to about 3, compared to about 2.8 in the related art, that is, the internal pressure of the vacuum vessel 32 increases about 1.1 times higher than that in the related art. The internal pressure of the vacuum vessel 32 at a rotation angle of 0 deg (i.e., in the valve-closed position) rises to about 4.2, compared to about 3 in the related art, that is, the internal pressure of the vacuum vessel 32 increases about 1.4 times higher than that in the related art.

The data indicated by “valve element 9 (3 mm)” show that the internal pressure of the vacuum vessel 32 is generally maintained at a higher level, i.e., the conductance is reduced, than that indicated by “related art” at the rotation angle of 0 to 10 deg. In particular, the internal pressure of the vacuum vessel 32 at the rotation angle of 2 deg, indicated by “valve element 9 (3 mm)”, rises to about 4.2, compared to about 2.8 in the related art, that is, the internal pressure of the vacuum vessel 32 increases about 1.5 times higher than that in the related art. The internal pressure of the vacuum vessel 32 at the rotation angle of 0 deg (i.e., in the valve-closed position) rises to about 4.7, compared to 3 in the related art, that is, the internal pressure of the vacuum vessel 32 increases about 1.6 times higher than that in the related art.

The data indicated by “valve element 9 (5 mm)” show that the internal pressure of the vacuum vessel 32 is maintained at a higher level, i.e., the conductance is reduced, than that indicated by “related art” at a rotation angle of 3 to 10 deg, as in the “valve element 9 (3 mm)”. At the rotation angle of 0 to 2 deg, the internal pressure of the vacuum vessel 32, indicated by “valve element 9 (5 mm)”, is maintained higher than that indicated by “valve element 9 (3 mm)”. In particular, the internal pressure of the vacuum vessel 32 at the rotation angle of 0 deg (i.e., in the valve-closed position) rises to about 5.3, compared to about 3 in the related art, that is, the internal pressure of the vacuum vessel 32 increases about 1.8 times higher than that in the related art.

According to the butterfly valve elements 9, 51, as described above, the internal pressure of the vacuum vessel 32 when gas is supplied from the gas supply source 37 to the vacuum vessel 32 can be kept higher than the butterfly valve element in the related art.

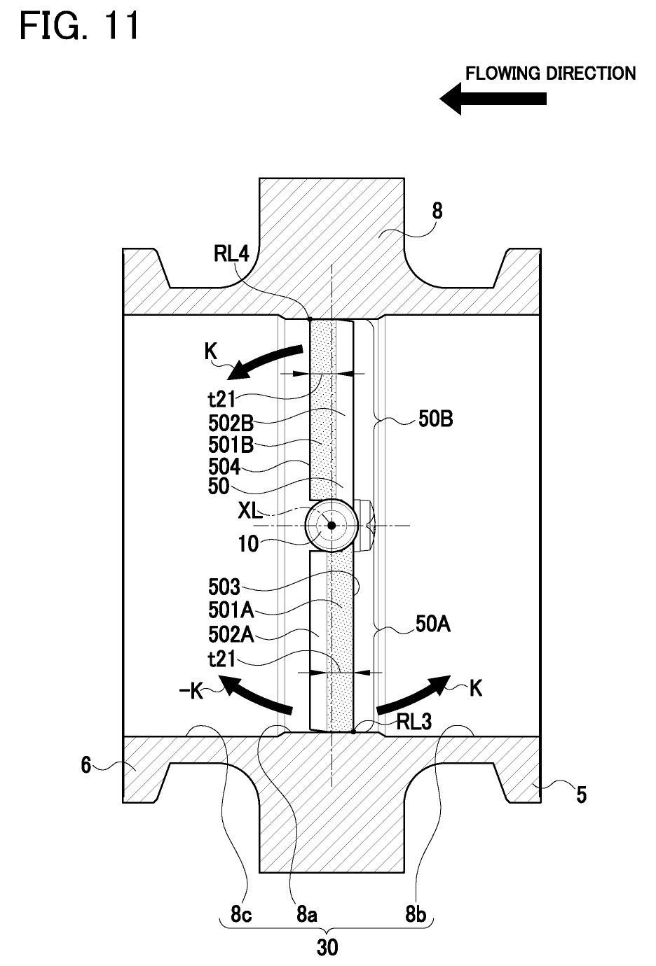

As shown by the data indicated by “valve element 9 (3 mm)” and “valve element 9 (5 mm)”, the larger the dimension t11 of the maximum outer diameter portion 91A, 91B, the smaller the conductance can be made, and the higher the internal pressure of the vacuum vessel 32 can be maintained. Therefore, to reduce the conductance, the butterfly valve element may be configured without the second chamfered portions 93A, 93B. This configuration is shown as a modified example referring to FIG. 11. FIG. 11 is a cross-sectional view, similar to FIG. 4, showing the non-sealed butterfly valve using a butterfly valve element 50 in the modified example.

The butterfly valve element 50 is configured such that a left half in the flowing direction at the valve-closed position, i.e., a lower-half section 50A in FIG. 11, and a right half in the flowing direction at the valve-closed position, i.e., an upper-half section 50B in FIG. 11, are point-symmetrical about the axis XL of the rod 10 when viewed in the axial direction of the rod 10. The outer peripheral edges of the sections 50A, 50B are provided with maximum outer diameter portions 501A, 501B and first chamfered portions 502A, 502B, but not provided with the second chamfered portions 93A, 93B. Accordingly, each maximum outer diameter portion 501A, 501B has a size (a dimension t21) in the thickness direction of the butterfly valve element 50, larger than the dimension t11. Since the butterfly valve element 50 is configured without the second chamfered portions 93A, 93B, the maximum outer diameter portions 501A, 501B of the butterfly valve element 50 can be increased in size without changing the thickness of the butterfly valve element, and can reduce the conductance.

However, if the butterfly valve element 50 rotates in the direction -K or during assembly of the butterfly valve 1, the ridge line RL3 at which an upstream-side end face 503 and the maximum outer diameter portion 501A of the butterfly valve element 50 intersect each other and the ridge line RL4 at which a downstream-side end face 504 and the maximum outer diameter portion 501B of the butterfly valve element 50 intersect each other may damage the inner peripheral surface of the flow passage 30. In this regard, as in the butterfly valve element 9, it is preferable to include the second chamfered portions 93A, 93B that reduce the diameter of the butterfly valve element 9 from the maximum outer diameter portions 91A, 91B in the rotation direction (the direction K), and that are arranged point-symmetrically about the axis XL. According to the butterfly valve element 9 including the second chamfered portions 93A, 93B, it is possible to reduce the risk of damage to the inner peripheral surface of the flow passage 30, which may be caused by rotation of the butterfly valve element 50 in the direction -K or during assembly of the butterfly valve 1, as described above.

The foregoing embodiments are mere examples and give no limitation to the disclosure. The disclosure may be embodied in other specific forms without departing from the essential characteristics thereof. For instance, in the above description, for simplification of description, the single gas supply source 37 is used. However, a plurality of gas supply sources may be connected to the vacuum vessel 32, and various types of gases to be supplied to the vacuum vessel 32 may be switched by switching valves or the like provided between the vacuum vessel 32 and the gas supply sources.

### REFERENCE SIGNS LIST

1 Non-sealed butterfly valve

9 Butterfly valve element

10 Rod

30 Flow passage

32 Vacuum vessel

33 Vacuum pump

91A Maximum outer diameter part

91B Maximum outer diameter part

92A First chamfered portion

92B First chamfered portion

What is claimed is:

1. A non-sealed butterfly valve to control pressure in a vacuum vessel, the non-sealed butterfly valve comprising:
a flow passage;
a rotary shaft placed extending in a direction perpendicular to the flow passage; and
a butterfly valve element having a circular disk shape, coupled to the rod and configured to rotate about an axis of the rotary shaft, between a valve-closed position for minimizing a flow passage area of the flow passage and a valve-open position for maximizing the flow passage area,
wherein the butterfly valve element includes:
maximum outer diameter portions facing an inner peripheral surface of the flow passage when the butterfly valve element is in the valve-closed position and being provided point-symmetrically about the axis of the rotary shaft when viewed in an axial direction of the rotary shaft; and
chamfered portions reducing a diameter of the butterfly valve element from the maximum outer diameter portions in a direction opposite a rotation direction of the butterfly valve element that rotates from the valve-closed position to the valve-open position and being provided point-symmetrically about the axis of the rotary shaft when viewed in an axial direction of the rotary shaft.

2. The non-sealed butterfly valve according to claim 1, wherein a dimension of each of the maximum outer diameter portions in a thickness direction of the butterfly valve element is greater than 0.5% and equal to or less than 10% of the flow passage.

3. The non-sealed butterfly valve according to claim 1, wherein an angle of each of the chamfered portions relative to a thickness direction of the butterfly valve element is equal to or less than 30°.

4. The non-sealed butterfly valve according to claim 2, wherein an angle of each of the chamfered portions relative to a thickness direction of the butterfly valve element is equal to or less than 30°.

5. The non-sealed butterfly valve according to claim 1, wherein the butterfly valve element includes second chamfered portions reducing the diameter of the butterfly valve element from the maximum outer diameter portions in the rotation direction, the second chamfered portions being provided symmetrically about the axis of the rotary shaft when viewed in the axial direction of the rotary shaft.

6. The non-sealed butterfly valve according to claim 2, wherein the butterfly valve element includes second chamfered portions reducing the diameter of the butterfly valve element from the maximum outer diameter portions in the rotation direction, the second chamfered portions being provided symmetrically about the axis of the rotary shaft when viewed in the axial direction of the rotary shaft.

7. The non-sealed butterfly valve according to claim 3, wherein the butterfly valve element includes second chamfered portions reducing the diameter of the butterfly valve element from the maximum outer diameter portions in the rotation direction, the second chamfered portions being provided symmetrically about the axis of the rotary shaft when viewed in the axial direction of the rotary shaft.

8. The non-sealed butterfly valve according to claim 1, wherein the chamfered portions have an angle with respect to an axis of the maximum outer diameter portions.

9. The non-sealed butterfly valve according to claim 2, wherein the chamfered portions have an angle with respect to an axis of the maximum outer diameter portions.

10. The non-sealed butterfly valve according to claim 3, wherein the chamfered portions have an angle with respect to an axis of the maximum outer diameter portions.

11. The non-sealed butterfly valve according to claim 4, wherein the chamfered portions have an angle with respect to an axis of the maximum outer diameter portions.

12. The non-sealed butterfly valve according to claim 1, further comprising a rotation restricting part for restricting the butterfly valve element from rotating in the direction opposite the rotation direction.

13. The non-sealed butterfly valve according to claim 2, further comprising a rotation restricting part for restricting the butterfly valve element from rotating in the direction opposite the rotation direction.

14. The non-sealed butterfly valve according to claim 3, further comprising a rotation restricting part for restricting the butterfly valve element from rotating in the direction opposite the rotation direction.

15. The non-sealed butterfly valve according to claim 5, further comprising a rotation restricting part for restricting the butterfly valve element from rotating in the direction opposite the rotation direction.

16. The non-sealed butterfly valve according to claim 8, further comprising a rotation restricting part for restricting the butterfly valve element from rotating in the direction opposite the rotation direction.

17. The non-sealed butterfly valve according to claim 1, further comprising a rotation restricting part for restricting the butterfly valve element from further rotating from the valve-open position in the rotation direction.

18. The non-sealed butterfly valve according to claim 2, further comprising a rotation restricting part for restricting the butterfly valve element from further rotating from the valve-open position in the rotation direction.
